(19) United States
(12) Patent Application Publication
(10) Pub. No.: US 2025/0220889 A1
(43) Pub. Date: Jul. 3, 2025

(54) METHODS OF FORMING MICROELECTRONIC DEVICES UTILIZING DIRECTED SELF-ASSEMBLY AND RELATED MICROELECTRONIC DEVICES

(71) Applicant: Micron Technology, Inc., Boise, ID (US)

(72) Inventors: Mitsunari Sukekawa, Hiroshima-shi (JP); Tomohiro Iwaki, Hiroshima (JP)

(21) Appl. No.: 18/956,895

(22) Filed: Nov. 22, 2024

Related U.S. Application Data
(60) Provisional application No. 63/616,065, filed on Dec. 29, 2023.

(51) Int. Cl. H10B 12/00

(52) U.S. Cl. CPC H10B 12/395; H10B 12/053

(57) ABSTRACT

A method of forming a microelectronic device includes forming first trenches in a semiconductor structure having semiconductor pillars interposed therebetween, and forming first insulative structures having a second insulative structure therein in the first trenches. The method also includes forming first conductive structures adjacent first ends of the semiconductor pillars and portions of the first insulative structures, and forming masks adjacent the first conductive structures and exposed portions of the first insulative structures, an uppermost mask being a neutral layer mask used to form a polymeric mask via directed self-assembly. The method further includes forming second trenches utilizing the polymeric mask, and removing portions of the first conductive structures exposed by third trenches to form first conductive members having openings therebetween. The method also includes forming second conductive structures adjacent sidewalls of the semiconductor pillars, and forming third conductive structures adjacent second ends of the semiconductor pillars.

### CROSS-REFERENCE TO RELATED APPLICATION

This application claims the benefit under 35 U.S.C. § 119 (e) of U.S. Provisional Patent Application Ser. No. 63/616,065, filed Dec. 29, 2023, the disclosure of which is hereby incorporated herein in its entirety by this reference.

### TECHNICAL FIELD

The disclosure, in various embodiments, relates generally to the field of microelectronic device design and fabrication. More specifically, the disclosure relates to methods of forming microelectronic devices utilizing directed self-assembly, and to related microelectronic devices, memory devices, and electronic systems.

### BACKGROUND

Microelectronic device designers often desire to increase the level of integration or density of features within a microelectronic device by reducing dimensions of the individual features and by reducing a separation distance between neighboring features. In addition, microelectronic device designers often desire to design architectures that are not only compact, but offer performance advantages, as well as simplified designs and/or fabrication techniques.

A relatively common microelectronic device is a memory device. Memory devices are generally provided as internal integrated circuits in computers or other electronic devices. There are many types of memory including, but not limited to, random-access memory (RAM) and dynamic random-access memory (DRAM).

### BRIEF DESCRIPTION OF THE DRAWINGS

For a detailed understanding of the disclosure, reference should be made to the following detailed description, taken in conjunction with the accompanying drawings, in which like elements have generally been designated with like numerals, and wherein:

FIGS. 1A through 12A are simplified top plan views of a microelectronic device structure at different processing stages of a method of forming a microelectronic device, in accordance with embodiments of the disclosure;

FIGS. 1B through 12B are simplified cross-sectional views corresponding to FIGS. 1A through 12A, respectively, along lines B-B thereof, in accordance with embodiments of the disclosure;

FIG. 5C is a simplified top plan view of an exemplary neutral layer mask comprising guide patterns, in accordance with embodiments of the disclosure; and

FIG. 13 is a schematic circuit diagram of a memory cell array including microelectronic devices, in accordance with embodiments of the disclosure.

### DETAILED DESCRIPTION

The following description provides specific details, such as material compositions, shapes, and sizes, in order to provide a thorough description of embodiments of the disclosure. However, a person of ordinary skill in the art would understand that the embodiments of the disclosure may be practiced without employing these specific details. Indeed, the embodiments of the disclosure may be practiced in conjunction with conventional microelectronic device fabrication techniques employed in the industry. In addition, the description provided below does not form a complete process flow for manufacturing a microelectronic device (e.g., a memory device). The structures described below do not form a complete microelectronic device. Only those process acts and structures necessary to understand the embodiments of the disclosure are described in detail below. Additional acts to form a complete microelectronic device from the structures may be performed by conventional fabrication techniques.

Drawings presented herein are for illustrative purposes only and are not meant to be actual views of any particular material, component, structure, device, or system. Variations from the shapes depicted in the drawings as a result, for example, of manufacturing techniques and/or tolerances, are to be expected. Thus, embodiments described herein are not to be construed as being limited to any particular shapes or regions as illustrated, but include deviations in shapes that result, for example, from manufacturing. For example, a region illustrated or described as box-shaped may have rough and/or nonlinear features, and a region illustrated or described as round may include some rough and/or linear features. Moreover, sharp angles that are illustrated may be rounded, and vice versa. Thus, the regions illustrated in the figures are schematic in nature, and their shapes are not intended to illustrate the precise shape of a region and do not limit the scope of the claims. The drawings are not necessarily to scale. Additionally, elements common between figures may retain the same numerical designation.

As used herein, a “memory device” means and includes a microelectronic device exhibiting memory functionality, but not necessarily limited to memory functionality. Stated another way, and by way of non-limiting example only, the term “memory device” includes not only conventional memory (e.g., conventional non-volatile memory; conventional volatile memory), but also includes an application specific integrated circuit (ASIC) (e.g., a system on a chip (SoC)), a microelectronic device combining logic and memory, and a graphics processing unit (GPU) incorporating memory.

As used herein, the terms “vertical,” “longitudinal,” “horizontal,” and “lateral” are in reference to a major plane of a structure and are not necessarily defined by earth's gravitational field. A “horizontal” or “lateral” direction is a direction that is substantially parallel to the major plane of the structure, while a “vertical” or “longitudinal” direction is a direction that is substantially perpendicular to the major plane of the structure. The major plane of the structure is defined by a surface of the structure having a relatively large area compared to other surfaces of the structure. With reference to the drawings, a “horizontal” or “lateral” direction may be perpendicular to an indicated “Z” axis (Z-direction), and may be parallel to an indicated “X” axis (X-direction) and/or parallel to an indicated “Y” axis (Y-direction); and a “vertical” or “longitudinal” direction may be parallel to an indicated “Z” axis, may be perpendicular to an indicated “X” axis, and may be perpendicular to an indicated “Y” axis.

As used herein, features (e.g., structures, materials, regions, devices) described as “neighboring” one another means and includes features of the disclosed identity (or identities) that are located most proximate (e.g., closest to) one another. Additional features (e.g., additional regions, additional structures, additional devices) not matching the disclosed identity (or identities) of the “neighboring” features may be disposed between the “neighboring” features. Put another way, the “neighboring” features may be positioned directly adjacent one another, such that no other feature intervenes between the “neighboring” features; or the “neighboring” features may be positioned indirectly adjacent one another, such that at least one feature having an identity other than that associated with at least one the “neighboring” features is positioned between the “neighboring” features. Accordingly, features described as “vertically neighboring” one another means and includes features of the disclosed identity (or identities) that are located most vertically proximate (e.g., vertically closest to) one another. Moreover, features described as “horizontally neighboring” one another means and includes features of the disclosed identity (or identities) that are located most horizontally proximate (e.g., horizontally closest to) one another.

As used herein, other spatially relative terms, such as “below,” “lower,” “bottom,” “above,” “upper,” “top,” and the like, may be used for ease of description to describe one element's or feature's relationship to another element(s) or feature(s) as illustrated in the figures. Unless otherwise specified, the spatially relative terms are intended to encompass different orientations of the materials in addition to the orientation as depicted in the figures. For example, if materials in the figures are inverted, elements described as “below” or “under” or “on bottom of” other elements or features would then be oriented “above” or “on top of” the other elements or features. Thus, the term “below” may encompass both an orientation of above and below, depending on the context in which the term is used, which will be evident to one of ordinary skill in the art. The materials may be otherwise oriented (rotated ninety degrees, inverted, etc.) and the spatially relative descriptors used herein interpreted accordingly.

As used herein, the terms “about” and “approximately,” when either is used in reference to a numerical value for a particular parameter, are inclusive of the numerical value and a degree of variance from the numerical value that one of ordinary skill in the art would understand is within acceptable tolerances for the particular parameter. For example, “about” or “approximately,” in reference to a numerical value, may include additional numerical values within a range of from 90.0 percent to 110.0 percent of the numerical value, such as within a range of from 95.0 percent to 105.0 percent of the numerical value, within a range of from 97.5 percent to 102.5 percent of the numerical value, within a range of from 99.0 percent to 101.0 percent of the numerical value, within a range of from 99.5 percent to 100.5 percent of the numerical value, or within a range of from 99.9 percent to 100.1 percent of the numerical value.

As used herein, the term “substantially,” when referring to a parameter, property, or condition, means and includes the parameter, property, or condition being equal to or within a degree of variance from a given value such that one of ordinary skill in the art would understand such given value to be acceptably met, such as within acceptable manufacturing tolerances. By way of example, depending on the particular parameter, property, or condition that is substantially met, the parameter, property, or condition may be “substantially” a given value when the value is at least 90.0 percent met, at least 95.0 percent met, at least 99.0 percent met, or even at least 99.9 percent met.

As used herein, “and/or” includes any and all combinations of one or more of the associated listed items.

As used herein, the singular forms “a,” “an,” and “the” are intended to include the plural forms as well, unless the context clearly indicates otherwise.

As used herein, the terms “configured” and “configuration” mean and refer to a size, shape, material composition, orientation, and arrangement of a referenced material, structure, assembly, or apparatus so as to facilitate a referenced operation or property of the referenced material, structure, assembly, or apparatus in a predetermined way.

As used herein, “conductive material” means and includes electrically conductive material such as one or more of a metal (e.g., tungsten (W), titanium (Ti), molybdenum (Mo), niobium (Nb), vanadium (V), hafnium (Hf), tantalum (Ta), chromium (Cr), zirconium (Zr), iron (Fc), ruthenium (Ru), osmium (Os), cobalt (Co), rhodium (Rh), iridium (Ir), nickel (Ni), palladium (Pd), platinum (Pt), copper (Cu), silver (Ag), gold (Au), aluminum (Al)), an alloy (e.g., a Co-based alloy, an Fe-based alloy, an Ni-based alloy, an Fe- and Ni-based alloy, a Co- and Ni-based alloy, an Fe- and Co-based alloy, a Co- and Ni- and Fe-based alloy, an Al-based alloy, a Cu-based alloy, a magnesium (Mg)-based alloy, a Ti-based alloy, a steel, a low-carbon steel, a stainless steel), a conductive metal-containing material (e.g., a conductive metal nitride, a conductive metal silicide, a conductive metal carbide, a conductive metal oxide), and a conductively doped semiconductor material (e.g., conductively doped polysilicon, conductively doped germanium (Ge), conductively doped silicon germanium (SiGe)). In addition, a “conductive structure” means and includes a structure formed of and including conductive material.

As used herein, “insulative material” means and includes electrically insulative material, such one or more of at least one dielectric oxide material (e.g., one or more of a silicon oxide (SiOₓ), phosphosilicate glass, borosilicate glass, borophosphosilicate glass, fluorosilicate glass, an aluminum oxide (AlOₓ), a hafnium oxide (HfOₓ), a niobium oxide (NbOₓ), a titanium oxide (TiOₓ), a zirconium oxide (ZrOₓ), a tantalum oxide (TaOₓ), and a magnesium oxide (MgOₓ)), at least one dielectric nitride material (e.g., a silicon nitride (SiN_{y})), at least one dielectric oxynitride material (e.g., a silicon oxynitride (SiOₓN_{y})), at least one dielectric oxycarbide material (e.g., silicon oxycarbide (SiOₓC_{y})), at least one hydrogenated dielectric oxycarbide material (e.g., hydrogenated silicon oxycarbide (SiCₓO_{y}H_{z})), and at least one dielectric carboxynitride material (e.g., a silicon carboxynitride (SiOₓC_{z}N_{y})). Formulae including one or more of “x,” “y,” and “z” herein (e.g., SiOₓ, AlOₓ, HfOₓ, NbOₓ, TiOₓ, SiN_{y}, SiOₓN_{y}, SiOₓC_{y}, SiCₓO_{y}H_{z}, SiOₓC_{z}N_{y}) represent a material that contains an average ratio of “x” atoms of one element, “y” atoms of another element, and “z” atoms of an additional element (if any) for every one atom of another element (e.g., Si, Al, Hf, Nb, Ti). As the formula are representative of relative atomic ratios and not strict chemical structure, an insulative material may comprise one or more stoichiometric compounds and/or one or more non-stoichiometric compounds, and values of “x,” “y,” and “z” (if any) may be integers or may be non-integers. As used herein, the term “non-stoichiometric compound” means and includes a chemical compound with an elemental composition that cannot be represented by a ratio of well-defined natural numbers and is in violation of the law of definite proportions. In addition, an “insulative structure” means and includes a structure formed of and including insulative material.

As used herein, the term “semiconductor material” refers to a material having an electrical conductivity between those of insulative materials and conductive materials. For example, a semiconductor material may have an electrical conductivity of between about 10-8 Siemens per centimeter (S/cm) and about 104 S/cm (10⁶ S/m) at room temperature. Examples of semiconductor materials include elements found in column IV of the periodic table of elements such as silicon (Si), germanium (Ge), and carbon (C). Other examples of semiconductor materials include compound semiconductor materials such as binary compound semiconductor materials (e.g., gallium arsenide (GaAs)), ternary compound semiconductor materials (e.g., Al_{X}Ga_{1-X}As), and quaternary compound semiconductor materials (e.g., Ga_{X}In_{1-X}As_{Y}P_{1-Y}), without limitation. Compound semiconductor materials may include combinations of elements from columns III and V of the periodic table of elements (III-V semiconductor materials) or from columns II and VI of the periodic table of elements (II-VI semiconductor materials), without limitation. Further examples of semiconductor materials include oxide semiconductor materials such as zinc tin oxide (ZnₓSn_{y}O, commonly referred to as “ZTO”), indium zinc oxide (InₓZn_{y}O, commonly referred to as “IZO”), zinc oxide (ZnₓO), indium gallium zinc oxide (InₓGa_{y}Zn₂O, commonly referred to as “IGZO”), indium gallium silicon oxide (InₓGa_{y}Si_{z}O, commonly referred to as “IGSO”), indium tungsten oxide (InₓW_{y}O, commonly referred to as “IWO”), indium oxide (InₓO), tin oxide (SnₓO), titanium oxide (TiₓO), zinc oxide nitride (ZnₓON_{z}), magnesium zinc oxide (MgₓZn_{y}O), zirconium indium zinc oxide (ZrₓIn_{y}Zn₂O), hafnium indium zinc oxide (HfₓIn_{y}Zn₂O), tin indium zinc oxide (SnₓIn_{y}Zn₂O), aluminum tin indium zinc oxide (AlₓSn_{y}In₂ZnₐO), silicon indium zinc oxide (SiₓIn_{y}Zn₂O), aluminum zinc tin oxide (AlₓZn_{y}Sn₂O), gallium zinc tin oxide (GaₓZn_{y}Sn₂O), zirconium zinc tin oxide (ZrₓZn_{y}Sn₂O), and other similar materials.

As used herein, the term “sacrificial material” means and includes a material that is formed and/or employed during a fabrication process but which is subsequently removed, in whole or in part, prior to completion of the fabrication process.

Unless the context indicates otherwise, the materials described herein may be formed by any suitable technique including, but not limited to, spin coating, blanket coating, chemical vapor deposition (CVD), plasma enhanced CVD (PECVD), atomic layer deposition (ALD), plasma enhanced ALD (PEALD), physical vapor deposition (PVD) (e.g., sputtering), or epitaxial growth. Depending on the specific material to be formed, the technique for depositing or growing the material may be selected by a person of ordinary skill in the art. In addition, unless the context indicates otherwise, removal of materials described herein may be accomplished by any suitable technique including, but not limited to, etching (e.g., dry etching, wet etching, vapor etching, atomic layer etching (ALE)), ion milling, abrasive planarization (e.g., chemical-mechanical planarization (CMP)), or other known methods.

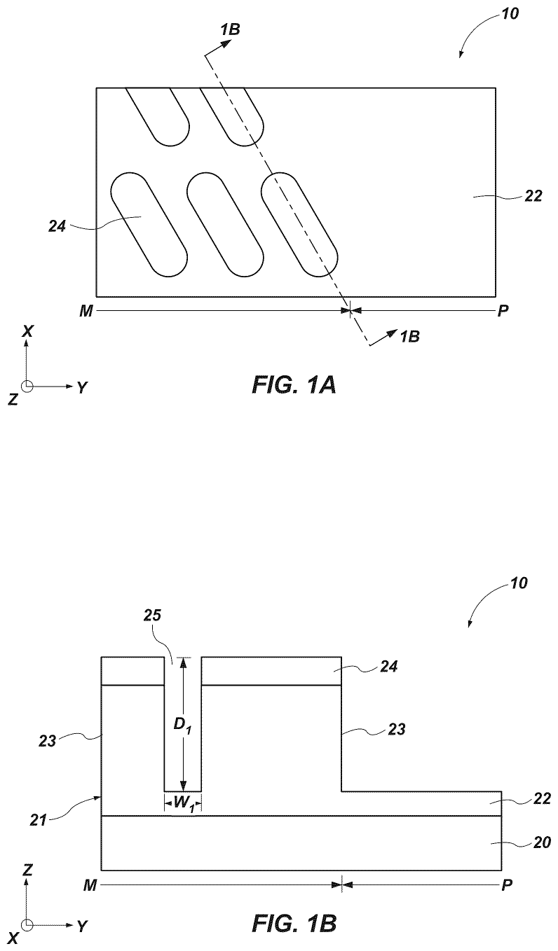

FIGS. 1A through 12A are simplified top plan views of a microelectronic device structure (e.g., a memory device structure, such as a DRAM device structure) at different processing stages of methods of forming a microelectronic device (e.g., a memory device, such as a DRAM device) utilizing directed self-assembly (DSA), in accordance with embodiments of the disclosure. FIGS. 1B through 12B are simplified cross-sectional views corresponding to FIGS. 1A through 12A, respectively, along lines B-B thereof. With the description provided below, it will be readily apparent to one of ordinary skill in the art that the methods described herein may be used to form various microelectronic devices, such as to form microelectronic devices advantageously utilizing directed self-assembly.

FIG. 1A is a top plan view of a microelectronic device structure 10 in accordance with embodiments of the disclosure, and FIG. 1B is a simplified cross-sectional view corresponding to the top plan view of FIG. 1A along lines 1B-1B thereof. Throughout the figures, and specifically, FIGS. 1A through 12B, an “A” designation following a numeric figure number shall indicate a top plan view while a “B” designation shall indicate a corresponding cross-sectional view along lines B-B thereof. As may be seen from FIGS. 1A and 1B, the microelectronic device structure 10 includes a memory cell region “M” and a peripheral region “P.”

Referring initially to FIGS. 1A and 1B, a microelectronic device structure 10 includes a first substrate 20. A configuration of the structures formed by directed self-assembly (DSA) is related to the surface energy of a surface of the first substrate 20. In cases where the surface energy of the substrate surface is not conducive to DSA, the surface energy may be modified (e.g., improved) by forming additional structure on the substrate surface (e.g., cylindrical structures, lamellar structures, gyroid structures, spherical structures). In some embodiments, the first substrate 20 is formed of and includes a material which beneficially affects the surface energy to facilitate the DSA process, which is described in detail hereinafter. The first substrate 20 may be formed of and include at least one insulative material (e.g., silicon dioxide).

A microelectronic device structure 10 in accordance with embodiments of the disclosure includes a semiconductor structure 21 formed adjacent to (e.g., on, over) the first substrate 20 by any suitable process (e.g., blanket coating, chemical vapor deposition (CVD), physical vapor deposition (PVD) (e.g., sputtering)). The semiconductor structure 21 includes a base 22 and semiconductor pillars 23 formed of a semiconductor material and extending (e.g., extending vertically upward in the Z-direction) from and integral with (e.g., unitary with) the base 22. The semiconductor structure 21 may be formed of and include at least one semiconductor material, such as silicon (e.g., monocrystalline silicon, polycrystalline silicon).

In addition, the microelectronic device structure 10 includes first trenches 25 extending into (e.g., extending vertically downward in the Z-direction) the semiconductor structure 21 in parallel with one another, and interposed between neighboring semiconductor pillars 23 in the Y-direction. With reference again to FIGS. 1A and 1B, a first mask 24 is formed adjacent to (e.g., on, over) the semiconductor structure 21 and patterned, and the first trenches 25 may be formed by a first material removal process (e.g., a first process including photolithographic patterning via the first mask 24 and etching) into the semiconductor structure 21. The first mask 24 may be formed of a sacrificial material (e.g., a hard mask material or a photoresist material). The first material removal process may also remove at least a portion of the semiconductor structure 21 adjacent to (e.g., on, over) the peripheral region P of the microelectronic device structure 10.

The first trenches 25 may be formed to terminate at a first depth D₁ into the semiconductor structure 21 (e.g., a depth from an uppermost surface of the first mask 24 to an upper surface of the base 22), as shown in FIG. 1B. For example, the first depth D₁ may range from about 100 nanometers (nm) to about 250 nm, such as from about 150 nm to about 200 nm (e.g., about 150 nm). In some embodiments, the portion of the semiconductor structure 21 adjacent to (e.g., on, over) the peripheral region P of the microelectronic device structure 10 is also removed to the first depth D₁. The first trenches 25 may exhibit a first width W₁ which is at least partially defined by a distance between the sidewalls of neighboring ones of the semiconductor pillars 23, as also shown in FIG. 1B. The first width W₁ of the first trenches 25 may be from about 5 nm to about 25 nm, or from about 5 nm to about 15 nm, or from about 15 nm to about 25 nm (e.g., about 20 nm).

With continued reference to FIGS. 1A and 1B, in some embodiments, the semiconductor pillars 23 have a generally oblong (e.g., oval, island-shaped) configuration. In some embodiments, the semiconductor pillars 23 have substantially constant widths along lengths thereof. In other embodiments, the semiconductor pillars 23 have a tapered configuration (not shown) being narrower near the top and wider near the bottom (e.g., wider proximate the base 22 of the semiconductor structure 21).

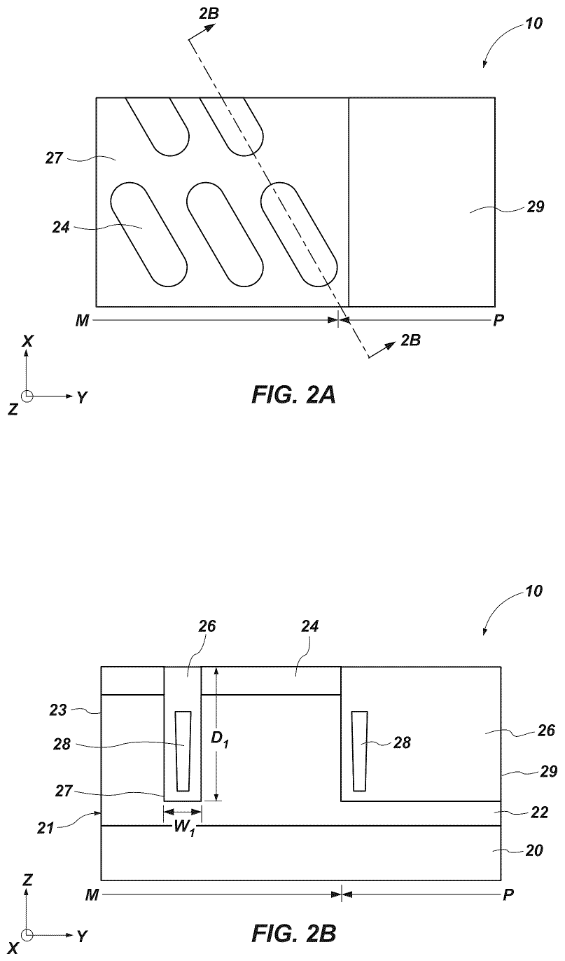

Referring next to FIGS. 2A and 2B, an insulative material 26 is formed by any suitable process (e.g., non-conformally deposited) to substantially fill the first trenches 25 (FIG. 1B) and to fill in the portion of the microelectronic device structure 10 adjacent to (e.g., on, over) the base 22 and the peripheral region P. Insulative material 26 may include, but is not limited to, one or more of a dielectric oxide material (e.g., silicon dioxide) and a dielectric nitride material (e.g., silicon nitride). First insulative structures 27 are formed by the insulative material 26 within the first trenches 25 (FIG. 1B) between the semiconductor pillars 23. The first insulative structures 27 may alternate with the semiconductor pillars 23 in the Y-direction. In addition, the first insulative structures 27 may extend substantially parallel to the semiconductor pillars 23. In some embodiments, the upper surfaces of the first insulative structures 27 are substantially coplanar with upper surfaces of the first mask 24 remaining adjacent to (e.g., on, over) the semiconductor pillars 23. The coplanar upper surfaces of the first insulative structures 27 and the upper surfaces of the first mask 24 may be formed using a suitable planarization process, such as chemical-mechanical planarization (CMP).

Second insulative structures 28 may be formed in the insulative material 26 of the first insulative structures 27 adjacent to (e.g., on, over) the memory cell region M of the microelectronic device structure 10 (e.g., in the first insulative structures 27 between the semiconductor pillars 23), as shown in FIG. 2B. In accordance with some embodiments, the second insulative structures 28 are configured and disposed to separate active areas and to minimize (e.g., prevent) electric current leakage between neighboring ones of the semiconductor pillars 23 of the microelectronic device structure 10. The second insulative structures 28 may be formed of one or more of the insulative materials, such as a doped insulative material. In some embodiments, the second insulative structures 28 are formed of phosphorus doped polysilicon (DOPOS).

Third insulative structures 29 may be formed adjacent to (e.g., on, over) the base 22 in the peripheral region P of the microelectronic device structure 10. The third insulative structures 29 may be formed of the same insulative material as insulative material 26 or of an insulative material that is different than insulative material 26. One or more second insulative structure 28 may also be formed in the third insulative structures 29, such as is shown in FIG. 2B. As before, the second insulative structures 28 may be formed of a doped insulative material. In some embodiments, the second insulative structures 28 are formed in the third insulative structures 29 of phosphorus doped polysilicon (DOPOS).

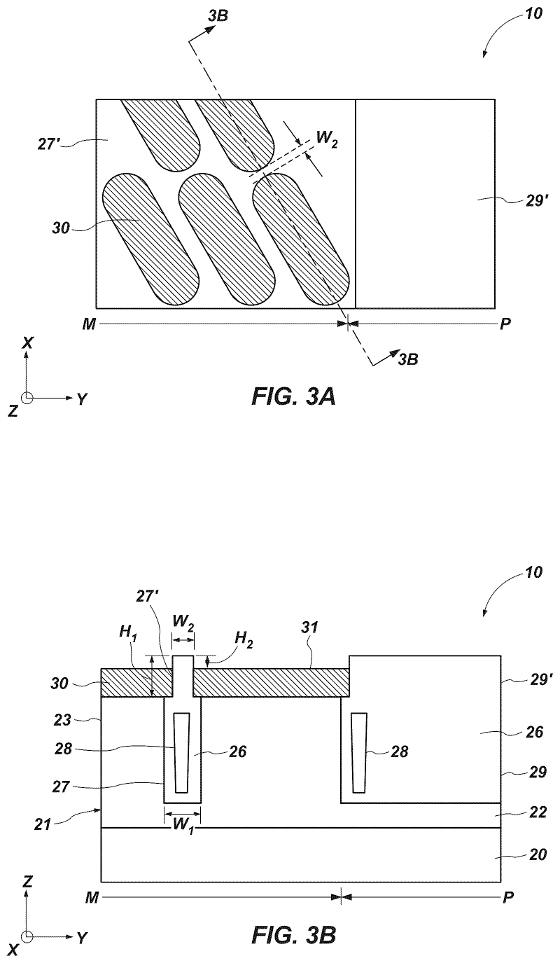

A second material removal process (e.g., wet etching, dry etching) is conducted to remove the first mask 24 from the microelectronic device structure 10. The second material removal process may also remove a portion of the first insulative structures 27 to form upper sections 27′ of the first insulative structures 27. The second material removal process may be conducted in one or more acts. In a first act, the first mask 24 is removed by a first wet etching process, exposing upper surfaces of the semiconductor pillars 23 thereunder. In a second act, a second wet etching process is conducted to remove upper portions of the first insulative structures 27 forming the upper sections 27′ thereof, along with removing upper portions of the third insulative structures 29 to form upper sections 29′ thereof. As may be seen from FIGS. 3A and 3B, the upper sections 27′ of the first insulative structures 27 exhibit a second width W₂. In some embodiments, the first width W₁ is greater than the second width W₂, such that the width of the upper sections 27′ is slimmed relative to the first width W₁ of the as-formed first insulative structures 27 (i.e., the first width W₁ of the lower sections of the first insulative structures 27). The second width W₂ of the upper sections 27′ of the first insulative structures 27 may range from about 5 nm to about 25 nm, or from about 5 nm to about 15, or from about 10 nm to about 20 nm (e.g., about 10 nm). Shoulder regions are formed between the sidewalls of the lower sections of the first insulative structures 27 and the sidewalls of the upper sections 27′.

With continued reference to FIGS. 3A and 3B, first conductive structures 30 are formed adjacent to (e.g., on, over) the semiconductor pillars 23, as well as along portions of the sidewalls of upper sections 27′ and upper sections 29′. The first conductive structures 30 may function as source/drain lines. As may be seen from FIG. 3B, the first conductive structures 30 may extend adjacent to (e.g., on, over) the shoulder regions of the first insulative structures 27, and between the portions of the sidewalls of the upper sections 27′ of the first insulative structures 27 and the portions of the sidewalls of the upper sections 29′ of the third insulative structures 29. The first conductive structures 30 may be formed of one or more conductive materials, such as titanium, titanium nitride, cobalt, molybdenum, or tungsten. In some embodiments, the first conductive structures 30 may be formed of titanium nitride and tungsten. In other embodiments, the first conductive structures may be formed of one or more of titanium, cobalt, and molybdenum.

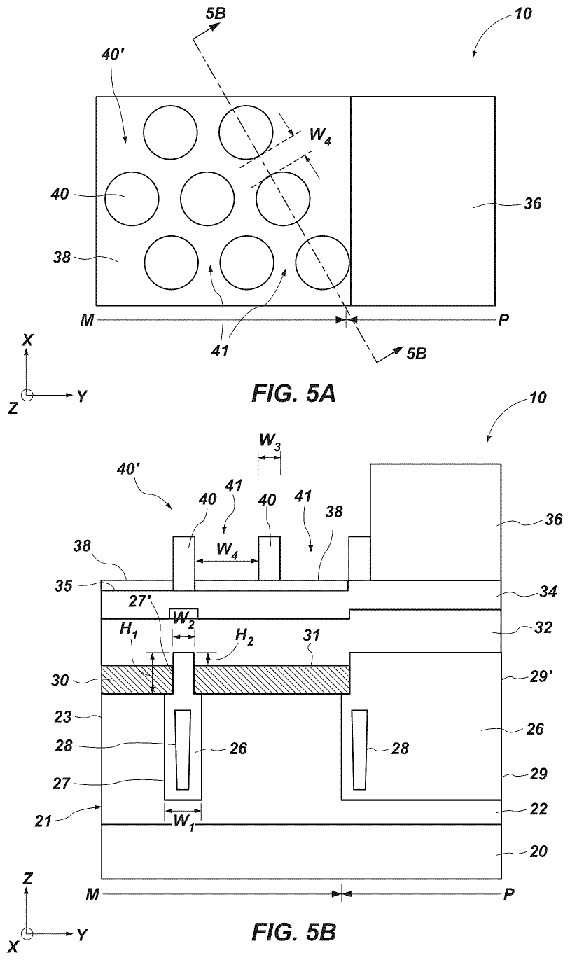

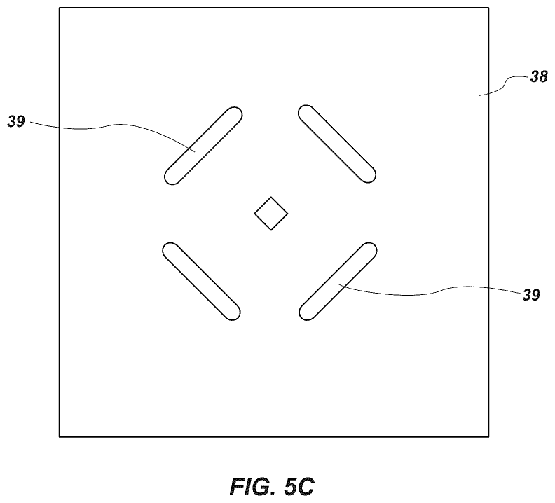

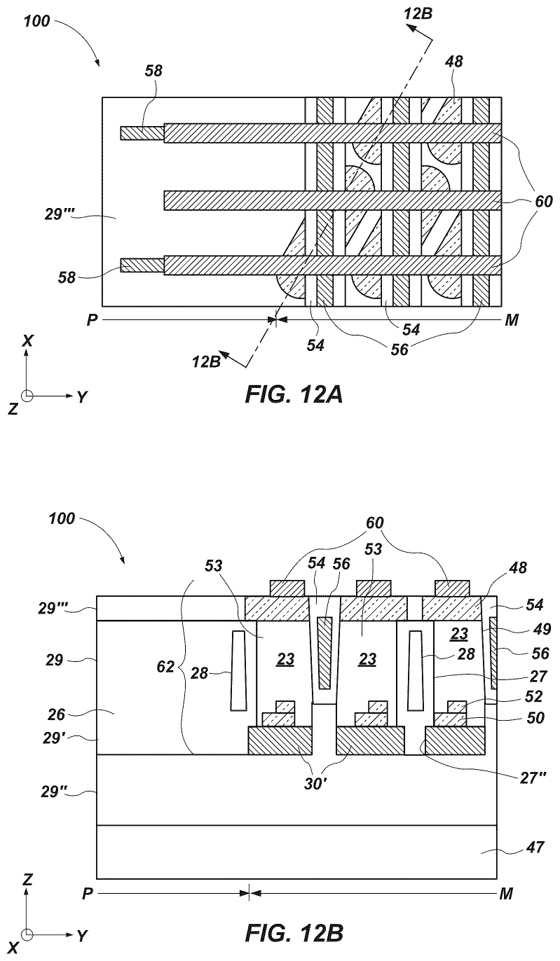

The reduction in the width (e.g., slimming) of the upper sections 27′ of the first insulative structures 27 from a first width W₁ to a second width W₂ results in an increase in the lateral dimensions of the first conductive structures 30 disposed between the upper sections 27′ of the first insulative structures 27, which results in an increase in (e.g., enlargement of) the active area of the first conductive structures 30. The increase in the active area of the first conductive structures 30 enables an improved (e.g., increased) current flow therethrough, resulting in improved (e.g., greater) operating efficiency of a microelectronic device 100 (see FIGS. 12A and 12B) including the microelectronic device structures 10. The upper sections 27′ extend (e.g., extend vertically upward in the Z-direction) from shoulder regions between the sidewalls of the insulative structures 27 and the sidewalls of the upper sections 27′. In some embodiments, the upper sections 27′ extend between and above the upper surfaces 31 of the first conductive structures 30, as shown in FIG. 3B. The upper sections 27′ exhibit a first height H₁ that substantially corresponds to a thickness of the first mask 24 (FIGS. 1B and 2B). The first height H₁, in some embodiments, may be from about 5 nm to about 50 nm, or from about 10 nm to about 40 nm, or from about 20 nm to about 30 nm (e.g., about 25 nm). A second height H₂ is exhibited by portions of the upper sections 27′ of the first insulative structures 27 which extend (e.g., extend vertically upward in the Z-direction) beyond the upper surfaces 31 of the first conductive structures 30. The second height H₂, in some embodiments, may be from about 2 nm to about 15 nm, or from about 3 nm to about 10 nm, or from about 4 nm to about 6 nm (e.g., about 5 nm). The second height H₂ corresponds to a step height (e.g., protrusion) of subsequent conformally formed materials. Additionally, the step height (e.g., protrusion) of subsequent conformally formed materials resulting from the second height H₂ at least partially defines a thickness of a neutral layer mask 38 (FIG. 5B) utilized in a directed self-assembly process, described in greater detail below.

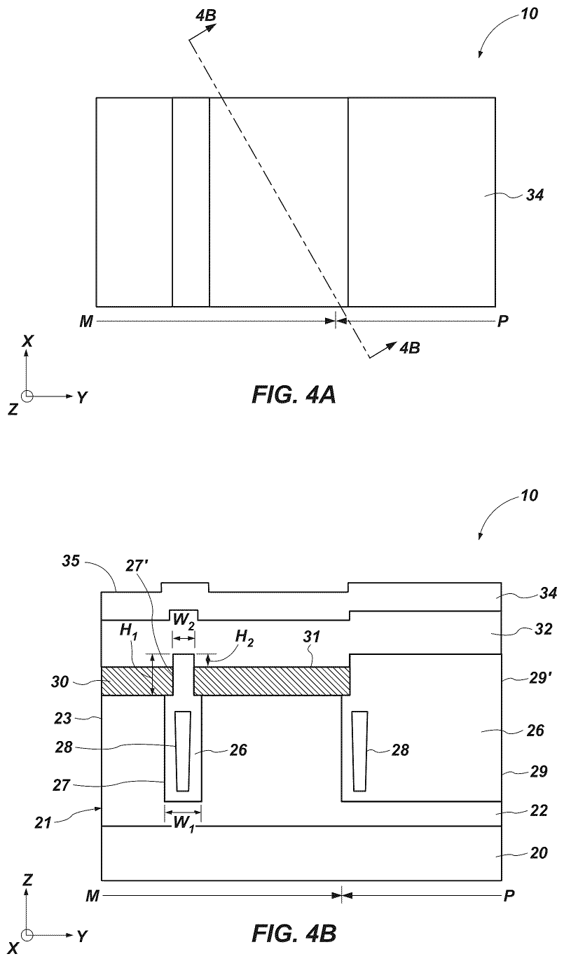

Referring next to FIGS. 4A and 4B, a second mask 32 is formed (e.g., conformally formed) adjacent to (e.g., on, over) the first conductive structures 30, the upper sections 27′ of the first insulative structures 27, and the upper sections 29′ of the third insulative structures 29. In some embodiments, the second mask 32 is formed of carbon (e.g., amorphous carbon). A third mask 34 may be formed (e.g., conformally formed) adjacent to (e.g., on, over) the second mask 32. The third mask 34 may be formed from any suitable mask materials (e.g., silicon oxynitride, silicon dioxide, silicon nitride, spun on glass). Since the second mask 32 and the third mask 34 are conformally formed, the topography (e.g., protrusions) of the upper sections 27′ of the first insulative structures 27 and the upper sections 29′ of the third insulative structures 29 are translated into the second mask 32 and the third mask 34. Therefore, upper surfaces 35 of the third mask 34 adjacent to (e.g., on, over) the upper sections 27′ of the first insulative structures 27 include the topography (e.g., protrusion, step height) corresponding to the height H₂ between the upper surfaces 31 of the first conductive structures 30 and uppermost surfaces of the upper sections 27′, as shown in FIG. 4B.

With reference to FIGS. 5A and 5B, a neutral layer mask 38 (e.g., a lamella mask) is formed adjacent to (e.g., on, over) the upper surfaces 35 of the third mask 34 in the memory cell region M of the microelectronic device structure 10. Portions of the neutral layer mask 38 adjacent to (e.g., overlying) the topography (e.g., protrusions, step height) of the upper sections 27′ of the first insulative structures 27 translated into the third mask 34 may be removed so that the upper surfaces 35 of the third mask 34 and the upper surfaces of the neutral layer mask 38 are coplanar with one another. As may be seen from FIG. 5B, the thickness of the neutral layer mask 38 is at least partially defined by the topography (e.g., protrusions, step height) resulting from the second height H₂ of the upper sections 27′ of the first insulative structures 27 translated into the third mask 34. A fourth mask 36 (e.g., photoresist mask) is formed adjacent to (e.g., on, over) the portion of the third mask 34 in the peripheral region P of the microelectronic device structure 10, which lacks (e.g., does not have) the neutral layer mask 38 formed thereover. The fourth mask 36 protects the peripheral region P of the microelectronic device structure 10 during the directed self-assembly process, as described below.

A directed self-assembly (DSA) process may be conducted utilizing any suitable self-assembling block copolymer materials, which phase separate and align during processing (e.g., annealing). During the DSA process, polymer blocks of the block copolymer material phase separate and self-assemble into the respective polymer blocks, forming ordered domains at nanometer-scale dimensions. The domain size may range from about 5 nm to about 55 nm, such as from about 5 nm to about 50 nm or from about 10 nm to about 55 nm. By way of example only, if the block copolymer material is a diblock copolymer, the block copolymer material may self-assemble into A blocks and B blocks. However, other block copolymer materials may be used, such as triblock or multiblock copolymers. A film morphology, including the domain size and period (Lₒ) (e.g., Lₒ of from about 15 nm to about 50 nm) of the microphase-separated domains, may be controlled by a chain length of block copolymer, molecular weight (MW) and volume fraction of the AB blocks to produce, for example, lamellar morphologies. After self-assembly, one of the block copolymers may be selectively removed to form a pattern of polymeric structures (e.g., polymeric structures 40) having a third width W₃ of nanometer size, such as from about 2 nm to about 100 nm (e.g., from about 10 nm to about 100 nm, from about 5 nm to about 30 nm, from about 5 nm to about 15 nm, from about 2 nm to about 15 nm). The pattern is used as a mask to form nanosized features (e.g., sub-lithographic features not readily or uniformly attainable via photolithography) in underlying materials. The nanosized features may range in width from about 10 nm to about 100 nm, such as from about 10 nm to about 50 nm, from about 10 nm to about 40 nm, from about 10 nm to about 30 nm, or from about 10 nm to about 20 nm.

In some embodiments in accordance with the disclosure, the DSA process utilizes a polystyrene-block-poly(methyl methacrylate) (PS-b-PMMA) block copolymer. The properties of the block copolymer (e.g., PS-b-PMMA block copolymer) control the size, shape, and uniformity of the polymeric structures (e.g., polymeric structures 40) formed via the DSA process. A PS-b-PMMA block copolymer is applied (e.g., spin coated) adjacent to (e.g., on, over) the neutral layer mask 38 from a dilute solution of the block copolymer in an organic solvent. In some embodiments, a thin layer or film (e.g., a thin layer or film having a thickness of from about 40 nm to about 100 nm) of the PS-b-PMMA block copolymer material may be deposited over the neutral layer mask 38, after which the PS-b-PMMA block copolymer is exposed to an annealing act. The annealing acts result in a phase separation between the block copolymers (e.g., polystyrene and the poly(methyl methacrylate)), forming an array of polystyrene structures and poly(methyl methacrylate) structures which are self-aligned (e.g., self-assembled) in a well-defined, high contrast pattern adjacent to (e.g., on, over) the neutral layer mask 38. In some embodiments, the neutral layer mask 38 may include guide patterns 39 formed thereon. FIG. 5C is illustrative of a neutral layer mask 38 (e.g., a lamella mask) having guide patterns 39 formed thereon. The guide patterns 39 at least partially define the initial locations for the self-alignment (e.g., self-assembly) of the array of polystyrene structures and poly(methyl methacrylate) structures during the annealing act. The density of the guide patterns 39 is typically much less than the density of the polymeric structures (e.g., polymeric structures 40) formed adjacent to (e.g., on, over) the neutral layer mask 38. This is a result of pattern multiplication which occurs in the block copolymer (e.g., the PS-b-PMMA block copolymer) during the annealing act.

In some embodiments, the block copolymer is exposed to a thermal annealing act. The thermal annealing act may be carried out at temperatures in the range of about 200 degrees Celsius (° C.) to about 300° C., or about 220° C. to about 280° C., or about 240° C. to about 260° C. (e.g., about 260° C.). Additionally, the thermal annealing act may be performed for a predetermined amount of time to obtain a desired contrast between the individual blocks of the block copolymer, such as about 1 minute to about 10 minutes, or about 2 minutes to about 8 minutes, or about 4 minutes to about 6 minutes (e.g., about 5 minutes). The fourth mask 36 protects the peripheral region P of the microelectronic device structure 10 during the DSA process (e.g., annealing). In some embodiments, the annealing act is conducted under an inert gas (e.g., nitrogen) environment. In other embodiments, the block copolymer is exposed to a chemical annealing act to effectuate phase separation and subsequent self-alignment (i.e., self-assembly) of the different components of the block copolymer.

Upon completion of the annealing act, a third material removal process may be conducted to selectively remove one of the copolymer structures (e.g., removal of the poly(methyl methacrylate) structures) with the other of the copolymer structures (e.g., polystyrene structures) remaining in a well-defined array adjacent to (e.g., on, over) the neutral layer mask 38. As may be seen from FIGS. 5A and 5B, after the annealing act and the third material removal processes, the polymeric structures 40 (e.g., polystyrene structures) remain in a highly-defined array adjacent to (e.g., on, over) the upper surfaces of the neutral layer mask 38. Specifically, the highly-defined array of polymeric structures 40 at least partially defines a self-assembled polymeric mask 40′. As used herein, a “highly-defined array” of polymeric structures 40 means and includes an array of polymeric structures 40 having a pitch (i.e., a distance from center to center of directly adjacent ones thereof) of from about 15 nm to about 50 nm, wherein the individual polymeric structures 40 have an effective diameter (e.g., third width W₃) of from about 2 nm to about 100 nm (e.g., from about 5 nm to about 30 nm). As may be seen from FIGS. 5A and 5B, the self-assembled polymeric mask 40′ forms second trenches 41 having fourth widths W₄ between neighboring ones of the polymeric structures 40. The fourth widths W₄ between neighboring ones of the polymeric structures 40 may range from about 5 nm to about 45 nm (e.g., from about 5 to about 25 nm).

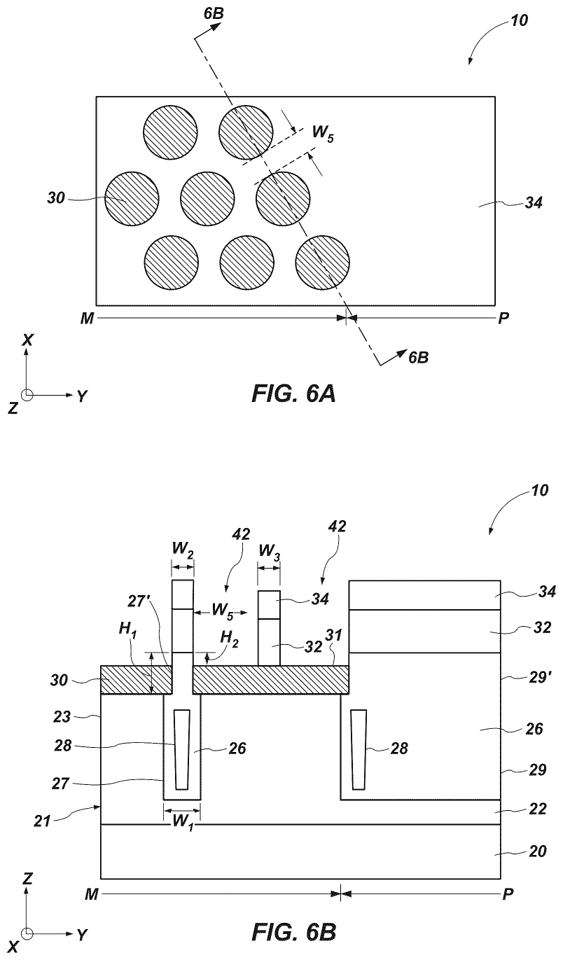

With reference next to FIGS. 6A and 6B, the self-assembled polymeric mask 40′ (FIGS. 5A and 5B) serves as a mask for the formation of third trenches 42 having fifth widths W₅ extending into (e.g., extending vertically downward in the Z-direction) and through both the third mask 34 and the second mask 32, exposing the upper surfaces 31 of the first conductive structures 30. The fifth widths W₅ of the third trenches 42 may be substantially the same as the fourth widths W₄ between neighboring ones of the polymeric structures 40 of the self-assembled polymeric mask 40′ (FIGS. 5A and 5B), and thus, the fifth widths W₅ may also range from about 5 nm to about 45 nm (e.g., from about 5 nm to about 25 nm). A fourth material removal process (e.g., atomic layer etching (ALE)) may be utilized to form the third trenches 42, as well as to remove the self-assembled polymeric mask 40′ (FIGS. 5A and 5B), remaining portions of the neutral layer mask 38 (FIGS. 5A and 5B), and the fourth mask 36 (FIGS. 5A and 5B) adjacent to (e.g., on, over) the peripheral region P. As may be seen from FIGS. 6A and 6B, the third trenches 42 are bounded by portions of the third mask 34 and the second mask 32 underlying the polymeric structures 40 of the self-assembled polymeric mask 40′ (FIGS. 5A and 5B) and underlying the fourth mask 36 which remain following the fourth material removal process.

Upon completion of the fourth material removal process, and the formation of the third trenches 42, a fifth mask 43 may be formed in the third trenches 42 and adjacent to (e.g., on, over) the exposed portions of the third mask 34, the second mask 32, and the first conductive structures 30. The fifth mask 43 may be formed of any suitable sacrificial material (e.g., an oxide, silicon oxynitride, silicon nitride). The upper surface of the fifth mask 43 may be planarized using a suitable planarization process (e.g., CMP) to be co-planar with the upper surfaces of the third mask 34.

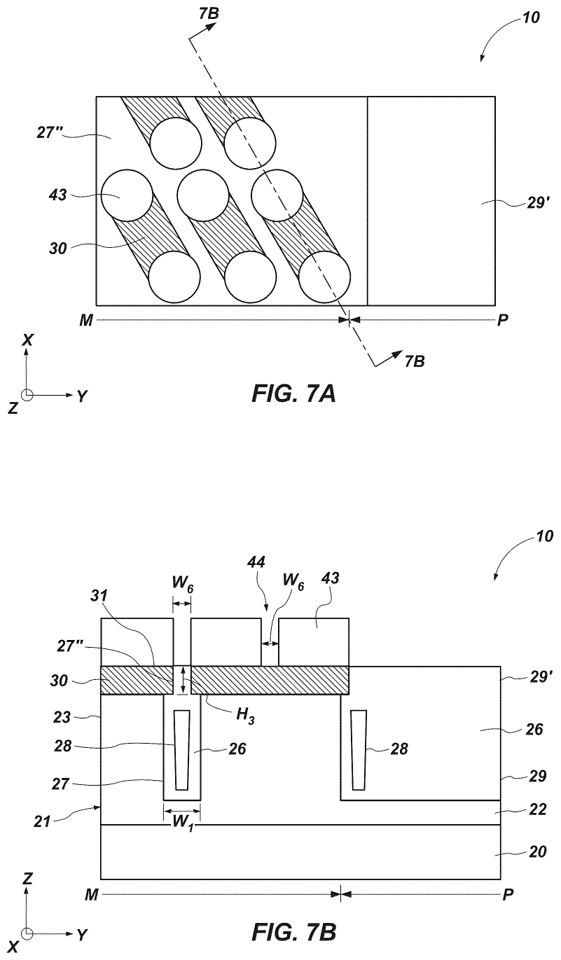

With reference to FIGS. 7A and 7B, a fifth material removal process may be employed to remove remaining portions of the third mask 34 (FIG. 6B) and the second mask 32 (FIG. 6B) to form fourth trenches 44 extending between (e.g., extending vertically downward in the Z-direction) portions of the fifth mask 43 to the upper surfaces 31 of the first conductive structures 30. The fourth trenches 44 may have sixth widths W₆ substantially equal to the third widths W₃ of the polymeric structures 40 (FIG. 5B) (i.e., from about 2 nm to about 100 nm, from about 2 nm to about 15 nm) utilized in the patterning of the fourth trenches 44. Upper portions of the upper sections 27′ (FIG. 6B) of the first insulative structures 27 and upper portions of the upper sections 29′ of the third insulative structures 29 may also be removed. Upper portions of the upper sections 27′ (FIG. 6B) of the first insulative structures 27 may further be planarized to form planarized upper sections 27″ having upper surfaces that are substantially coplanar with the upper surfaces 31 of the first conductive structures 30. The dimensions of the planarized upper sections 27″ are at least partially defined by second widths W₂, and third heights H₃, the third heights H₃ being less than first heights H₁ (FIG. 6B) of the upper sections 27′ (FIG. 6B). In some embodiments, the third heights H₃ are substantially equal to the first heights H₁ minus the second heights H₂. In some embodiments, the upper sections 29′ of the third insulative structures 29 may also be planarized to be coplanar with the upper surfaces 31 of the first conductive structures 30.

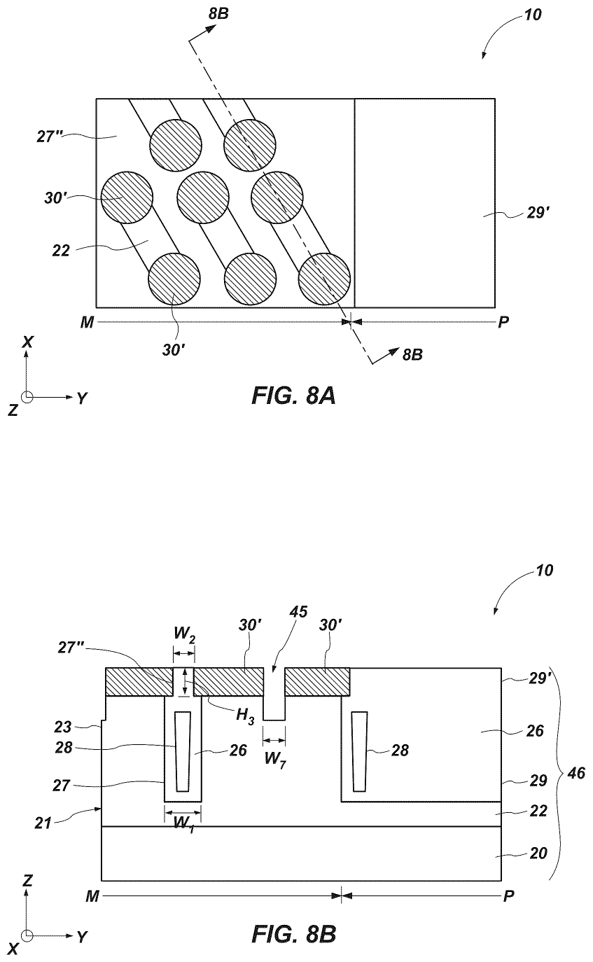

Referring to FIGS. 8A and 8B, the first conductive structures 30 are separated into discrete portions by removing portions of the first conductive structures 30 exposed through the fourth trenches 44 in the fifth mask 43 (FIG. 7B). Specifically, openings 45 are formed through portions of the first conductive structures 30 (FIGS. 7A and 7B) exposed through the fourth trenches 44 in the fifth mask 43 (FIGS. 7A and 7B) and at least partially into the underlying semiconductor pillars 23, thereby separating the first conductive structures 30 and creating first conductive members 30′. In some embodiments, the first conductive members 30′ may be operated independently of and electrically isolated from one another. The openings 45 exhibit a seventh width W₇ at least partially defining a distance between neighboring ones of the first conductive members 30′. The seventh widths W₇ of the openings 45 between the first conductive members 30′ are substantially equal to the sixth widths W₆ of fourth trenches 44 (FIG. 7B) which, as before, are substantially equal to the third widths W₃ of the polymeric structures 40 (FIG. 5B) (i.e., from about 2 nm to about 100 nm, from about 5 nm to about 15 nm). Thus, as a result of the self-assembled polymeric mask 40′ (FIGS. 5A and 5B) formed by the DSA process, substantially uniform, nanosized openings 45 may be formed through portions of conductive structures 30 to increase (e.g., maximize) the active area of the first conductive members 30′ formed therefrom. As with the first conductive structures 30 themselves, the increase in the active area of the first conductive members 30′ enables an improved (e.g., increased) current flow therethrough, resulting in improved (e.g., greater) operating efficiency of a microelectronic device 100 (see FIGS. 12A and 12B) including the microelectronic device structures 10 in accordance with embodiments of the disclosure. Additionally, the uniformity in size of the openings 45 between the first conductive members 30′ reduces (e.g., minimizes) instances of short circuits between the first conductive members 30′ such as may result from forming nanosized openings (e.g., openings 45) by other processes (e.g., photolithography).

As shown in FIG. 8B, an intermediate structure 46 includes the first substrate 20, the semiconductor structure 21, the first insulative structures 27, the second insulative structures 28, the third insulative structures 29, and the first conductive members 30′.

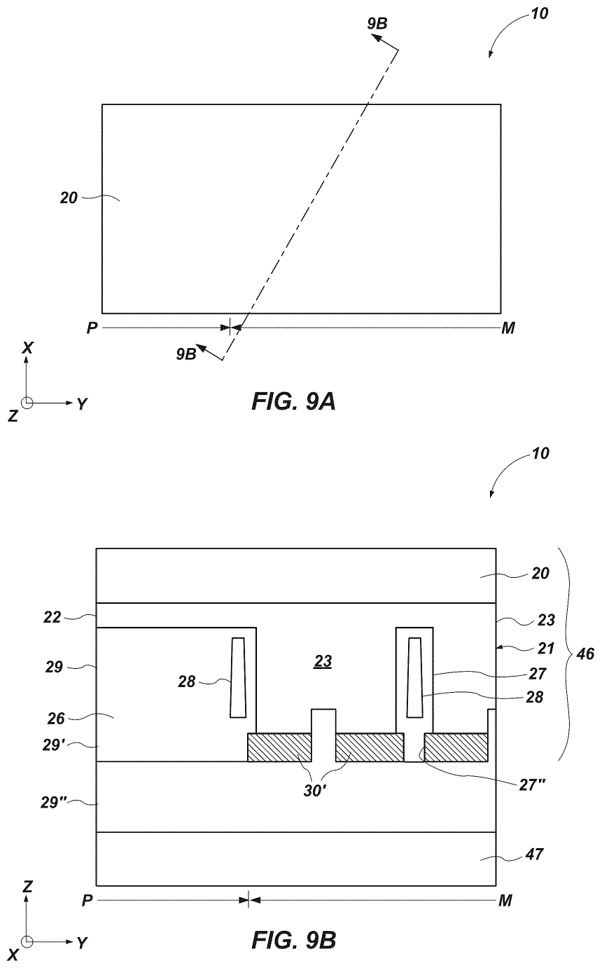

With reference to FIGS. 9A and 9B, fourth insulative structures 29″ are formed adjacent to (e.g., on, over) the intermediate structure 46 and into and filling the openings 45 between corresponding ones of the first conductive members 30′. The fourth insulative structures 29″ may be formed of the same or a different insulative material as the third insulative structures 29. In some embodiments, the fourth insulative structures 29″ are formed of insulative material 26 (e.g., silicon dioxide, silicon nitride). The intermediate structure 46 having the fourth insulative structures 29″ formed thereon is inverted and rotated 180 degrees, and the fourth insulative structures 29″ are bonded to a second substrate 47 by conventional techniques. The second substrate 47 may include any suitable material. In some embodiments, the second substrate 47 is formed of silicon. In at least some embodiments, the fourth insulative structures 29″ may be formed adjacent to (e.g., on, over) and bonded to the second substrate 47, after which, the intermediate structure 46 is inverted and bonded to the fourth insulative structures 29″, adjacent to (e.g., on, over) an opposing surface of the second substrate 47.

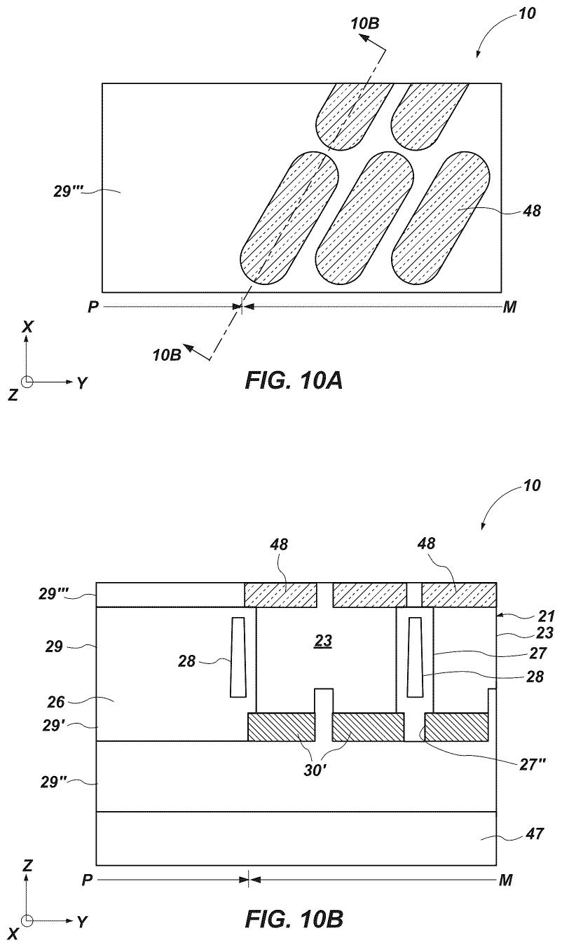

Referring to FIGS. 10A and 10B, a sixth material removal process is effectuated to remove the first substrate 20 (FIGS. 9A and 9B) and at least a portion of the base 22 adjacent to (e.g., on, over) the first insulative structures 27 and the third insulative structures 29, exposing upper surfaces of the semiconductor pillars 23. As shown in FIG. 10B, substantially all of the base 22 is removed. First doped regions 48 (e.g., source/drain regions) are formed in upper portions of the semiconductor pillars 23, as also shown in FIG. 10B. The doped regions 48 may function as channels during use and operation of the microelectronic device 100 (FIGS. 12A and 12B). Doping may be accomplished utilizing suitable processes, such as implanting of an appropriate dopant (e.g., n-type dopant, p-type dopant) into the upper portions of the semiconductor pillars 23. In some embodiments, the first doped regions 48 are individually n-type doped, such as to a concentration in a range of from about 1×10¹⁵ cm⁻³ to about 1×10²⁰ cm⁻³. As shown in FIG. 10B, the first doped regions 48 extend from the upper surfaces of and into the semiconductor pillars 23 (e.g., to a vertical depth of from about 20 nm to about 30 nm from upper surfaces of the semiconductor pillars 23). Such processing may be effectuated prior to the formation of fifth insulative structures 29′″ adjacent to (e.g., on, over) the exposed portions of the third insulative structures 29 and portions of the semiconductor pillars 23, as shown in FIG. 10B. The upper surfaces of the fifth insulative structures 29′″ and the first doped regions 48 may be planarized by any suitable process (e.g., CMP). In some embodiments, the fifth insulative structures 29′″ are formed adjacent to (e.g., on, over) the exposed portions of the third insulative structures 29 and portions of the semiconductor pillars 23, prior to forming the first doped regions 48.

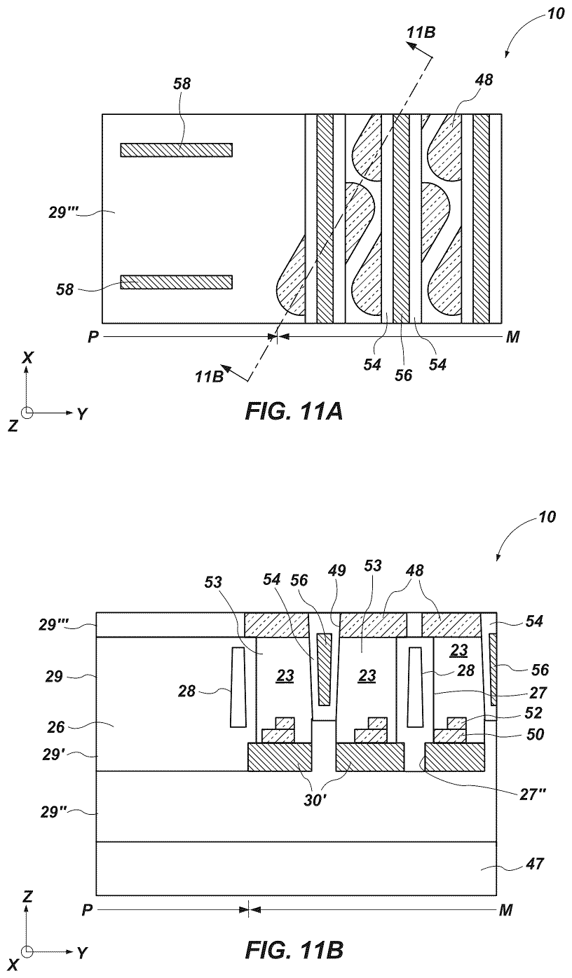

With reference to FIGS. 11A and 11B, fifth trenches 49 are formed through portions of the fifth insulative structures 29′″, the neighboring first doped regions 48, and into and at least partially through the semiconductor pillars 23. Second doped regions 50 and third doped regions 52 (e.g., source/drain regions) are formed in the lower portions of the semiconductor pillars 23 by any suitable process (e.g., accelerated voltage). Similar to the first doped regions 48, the second doped regions 50 and third doped regions 52 may be n-type doped or p-type doped to any suitable concentration. In some embodiments, the semiconductor pillars 23 include channel regions 53 disposed between the first doped regions 48 and the second and third doped regions 50, 52, respectively. The channel region 53 may be doped (e.g., an n-doped region, a p-doped region) or undoped (e.g., an undoped region).

With continued reference to FIGS. 11A and 11B, dielectric liners 54 (e.g., gate dielectric liners) are formed (e.g., deposited, conformally deposited) in and along at least the sidewalls of the fifth trenches 49. The dielectric liners 54 may be formed of and include an insulative material, such as an insulative oxide material. In other embodiments, the dielectric liners 54 are formed by oxidation of the exposed surfaces of the semiconductor pillars 23 along the sidewalls of the fifth trenches 49. Second conductive structures 56 are formed in the fifth trenches 49. In some embodiments, the second conductive structures 56 are substantially surrounded by the dielectric liners 54 within the fifth trenches 49. The second conductive structures 56 may include one or more conductive materials, as described above (e.g., titanium nitride). In some embodiments, the second conductive structures 56 form word lines (e.g., access lines).

In some embodiments, one or more third conductive structures 58 may be formed in the peripheral region P of the microelectronic device structure 10. The third conductive structures 58 facilitates connection (e.g., electrical connection) between components in the memory cell region M and components in the peripheral region P of the microelectronic device structure 10. With reference again to FIG. 11A, the third conductive structures 58 are formed in the peripheral region P and are disposed substantially perpendicular to the second conductive structures 56. The third conductive structures 58 may include one or more conductive materials, once again, as described above (e.g., titanium nitride).

Referring next to FIGS. 12A and 12B, fourth conductive structures 60 are formed adjacent to (e.g., on, over) portions of the first doped regions 48 of the semiconductor pillars 23, substantially perpendicular to the second conductive structures 56. As may be seen best in FIG. 12A, the fourth conductive structures 60 extend from the memory cell region M into the peripheral region P, to effect electrical connection between components therebetween. Similar to the second and third conductive structures 56, 58, respectively, the fourth conductive structures 60 are formed of and include one or more conductive materials, such as titanium nitride. In some embodiments, the fourth conductive structures 60 may form bit lines (e.g., digit lines).

As may be seen from FIG. 12B, the semiconductor pillars 23 form a portion of a vertical access device 62 (e.g., a vertical transistor). The vertical access devices 62 may include a channel region 53 of a semiconductor pillar 23, a source region including one of the first doped regions 48 or the second and third doped regions 50, 52, respectively, of the semiconductor pillar 23, and a drain region including the other of the first the doped regions 48 or the second and third doped regions 50, 52, respectively, of the semiconductor pillar 23. In some embodiments, a first conductive member 30′ is disposed in electrical communication with a corresponding one of the semiconductor pillars 23. More specifically, in some embodiments, the first conductive member 30′ is disposed in electrical communication with one of a source region or a drain region of a corresponding one of the semiconductor pillars 23. In addition, the vertical access device 62 may include a gate electrode including one of the second conductive structures 56 and a corresponding one of the dielectric liners 54, with the second conductive structures 56 and a corresponding one of the dielectric liners 54 disposed along a sidewall of the semiconductor pillar 23. One of the second conductive structures 56, and a corresponding one of the dielectric liners 54, may be utilized as a gate electrode for multiple vertical access devices 62. A fourth conductive structure 60 is disposed in electrical communication with the other of the source region or drain region of a corresponding one of the semiconductor pillars 23, opposite the first conductive member 30′. Similar to the gate electrode, one of the fourth conductive structures 60 may be employed as a source/drain line for multiple vertical access devices 62. The arrangement of the vertical access devices 62 in the memory cell region M and the third conductive structures 58 in the peripheral region P, electrically connected by the fourth conductive structures 60 (e.g., bit lines), at least partially form a microelectronic device 100 (e.g., a DRAM device). However, the microelectronic device 100 may be a different microelectronic device, such as a static random-access memory (SRAM), a flash memory, an erasable programmable read only memory (EPROM), a magneto-resistive random-access memory (MRAM), or a phase-change memory.

The methods described herein may be used to form microelectronic devices using significantly fewer process acts through the use of directed self-assembly (DSA). In addition, the methods described herein may be used to form microelectronic devices wherein the active areas of at least some conductive structures are increased as a result of the reduced widths of the upper sections of the first insulative structures between neighboring semiconductor pillars wherein at least some of the conductive structures are disposed. In addition, DSA may be used to form polymeric masks utilized, for example, to facilitate separation of at least some of the conductive structures into discrete conductive members having substantially uniform, nanosized openings formed therebetween, increasing the active areas of the conductive members. The increase in the active areas of the conductive members permits improved (e.g., increased) current flow therethrough, resulting in improved (e.g., greater) operating efficiency of microelectronic devices employing conductive members having the increased active areas. In addition, the uniformity in the nanosized openings between the conductive members reduces (e.g., minimizes) instances of short circuits between the first conductive members such as may result from forming nanosized openings by other processes (e.g., photolithography).

A method of forming a microelectronic device includes forming first trenches extending into a semiconductor structure comprising a base to form semiconductor pillars between adjacent ones of the first trenches, and forming first insulative structures in the first trenches, each first insulative structure having a second insulative structure therein. The method also includes forming first conductive structures adjacent to first ends of the semiconductor pillars and portions of the first insulative structures. The method further includes forming one or more masks adjacent to the first conductive structures and exposed portions of the first insulative structures, an uppermost one of the one or more masks comprising a neutral layer mask. The method includes forming a block copolymer adjacent to the neutral layer mask, annealing the block copolymer to form a self-assembled array of first polymeric structures and second polymeric structures, and selectively removing the first polymeric structures or the second polymeric structures, the remaining one of the first polymeric structures or the second polymeric structures forming a polymeric mask. The method also includes forming second trenches in the one or more masks utilizing the polymeric mask, forming a sacrificial material in the second trenches, and removing remaining portions of the one or more masks to form third trenches through the sacrificial material and expose upper surfaces of the first conductive structures. The method further includes removing portions of the first conductive structures exposed by the third trenches to form first conductive members having openings therebetween, forming second conductive structures adjacent to at least one sidewall of at least one of the semiconductor pillars, and forming third conductive structures adjacent to second ends of the semiconductor pillars.

Another method of forming a microelectronic device forming a semiconductor structure having a base, and forming first trenches extending into the semiconductor structure in a first direction and disposed in parallel with one another in a second direction, semiconductor pillars being formed and interposed between adjacent ones of the first trenches in the second direction. The method also includes forming insulative structures in the first trenches, wherein the insulative structures include a lower section exhibiting a first width at least partially defined by a horizontal distance between sidewalls of neighboring semiconductor pillars in the second direction, an upper section exhibiting a second width at least partially defined by a horizontal distance between sidewalls thereof in the second direction, the first width being greater than the second width, and shoulder regions formed between the sidewalls of the lower section of the insulative structure and the sidewalls of the upper section of the insulative structure. The method further includes forming first conductive structures adjacent to first ends of the semiconductor pillars and extending adjacent to the shoulder regions of neighboring insulative structures, and removing portions of the first conductive structures to form first conductive members having openings therebetween. The method also includes forming second conductive structures adjacent to one of the sidewalls of at least one of the semiconductor pillars, and forming third conductive structures adjacent to second ends of the semiconductor pillars.

A microelectronic device includes insulative structures disposed in a first direction and interposed between and alternating with semiconductor pillars in a second direction, each insulative structure having a lower section exhibiting a first width at least partially defined by a distance between sidewalls of neighboring semiconductor pillars in the second direction, an upper section exhibiting a second width at least partially defined by a distance between sidewalls thereof in the second direction, wherein the first width is greater than the second width, and shoulder regions between the sidewalls of the lower section of the insulative structure and the sidewalls of the upper section of the insulative structure. The microelectronic device also includes one or more vertical access devices, the vertical access devices including one of the semiconductor pillars, the one of the semiconductor pillars having oppositely disposed source/drain regions and a channel region vertically between the source/drain regions, a gate electrode adjacent to the one of the semiconductor pillars and in electrical communication therewith, and a first conductive member adjacent to one end of the one of the semiconductor pillars and extending adjacent to the shoulder regions of neighboring insulative structures, the first conductive member in electrical communication with one of the source/drain regions. The microelectronic device further includes a conductive structure in electrical communication with the other of the source/drain regions.

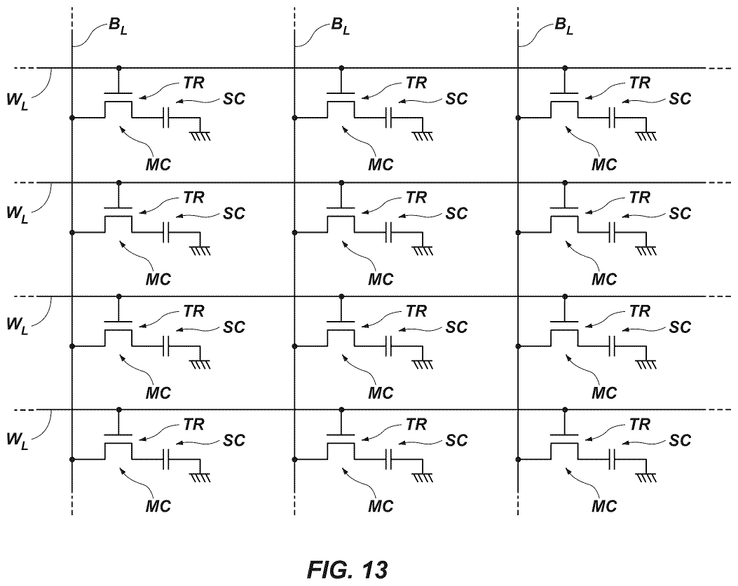

FIG. 13 is a schematic circuit diagram of a memory cell array including one or more microelectronic devices (e.g., microelectronic device 100) in accordance with embodiments of the disclosure. The memory cell array includes memory cells MC arranged in a matrix and connected proximate intersections of word lines W_{L} (e.g., second conductive structures 56) and bit lines B_{L} (e.g., fourth conductive structures 60), which are arranged perpendicular to one another and cross at right angles. The memory cells MC include a corresponding access transistor TR (e.g., vertical access device 62) and storage capacitor SC.

Gate electrodes (e.g., second conductive structures 56) of the access transistors TR (e.g., vertical access devices 62) may function as word lines W_{L} of a memory device (e.g., a DRAM device) and the word lines W_{L} (e.g., second conductive structures 56) may function as control lines for controlling selection of a corresponding memory cell MC. One of the source/drain regions of the access transistors TR (e.g., vertical access devices 62) is connected to a bit line B_{L} (e.g., fourth conductive structures 60) and the other is connected to a storage capacitor SC. Electric charges are accumulated in the storage capacitor SC to store data.

When the data are written into a memory cell MC, a potential for turning on the access transistor TR (e.g., vertical access devices 62) is applied to the word line W_{L} (e.g., second conductive structures 56), and a low potential or high potential, which corresponds to writing data “0” or “1,” respectively, is applied to the bit line B_{L} (e.g., fourth conductive structures 60). When data are read out from the memory cell MC, a potential for turning on the access transistor TR (e.g., vertical access device 62) is applied to the word line W_{L} (e.g., second conductive structures 56). As a result, the potential drawn from the storage capacitor SC to the bit line B_{L} (e.g., fourth conductive structures 60) is sensed by a sense amplifier (not shown) connected to the bit line B_{L} (e.g., fourth conductive structures 60), thereby performing data determinations.

Through the above acts, it is possible to form a microelectronic device (e.g., microelectronic device 100) including access transistors TR (e.g., vertical access devices 62) containing a first doped portion (e.g., first doped regions 48), a second semiconductor structure (e.g., semiconductor pillars 23), a second doped portion (e.g., second doped regions 50), and a third doped portion (e.g., third doped regions 52) arranged adjacent one another. The access transistors TR (e.g., vertical access devices 62) may be formed as metal-oxide-semiconductor field effect transistors (MOSFET) such that the channel regions (e.g., channel regions 53) formed in the second semiconductor structures (e.g., semiconductor pillars 23) extend in a vertical direction. An access transistor TR (e.g., vertical access devices 62) in which a channel region (e.g., channel regions 53) is formed in the vertical direction and source/drain regions are arranged in the vertical direction at upper and lower ends of the channel region (e.g., channel regions 53) is a vertical transistor. Accordingly, it is possible to form a structure in which the access transistors TR (e.g., vertical access device 62) and the storage capacitors SC are arranged in a vertically stacked direction. By arranging the access transistors TR (e.g., vertical access device 62) and the storage capacitors SC in this manner, the area occupied by the memory cells MC on the X-Y plane can be reduced, so that a highly integrated microelectronic device (e.g., microelectronic device 100) may be realized.

The embodiments of the disclosure described above and illustrated in the accompanying drawings do not limit the scope of the disclosure, which is encompassed by the scope of the appended claims and their legal equivalents. Any equivalent embodiments are within the scope of this disclosure. Indeed, various modifications of the disclosure, in addition to those shown and described herein, such as alternate useful combinations of the elements described, will become apparent to those skilled in the art from the description. Such modifications and embodiments also fall within the scope of the appended claims and equivalents.

What is claimed is:

1. A method of forming a microelectronic device, comprising:
forming first trenches extending into a semiconductor structure comprising a base to form semiconductor pillars between adjacent ones of the first trenches;
forming first insulative structures in the first trenches, each first insulative structure having a second insulative structure therein;
forming first conductive structures adjacent to first ends of the semiconductor pillars and portions of the first insulative structures;
forming one or more masks adjacent to the first conductive structures and exposed portions of the first insulative structures, an uppermost one of the one or more masks comprising a neutral layer mask;
forming a block copolymer adjacent to the neutral layer mask;
annealing the block copolymer to form a self-assembled array of first polymeric structures and second polymeric structures;
selectively removing the first polymeric structures or the second polymeric structures, the remaining one of the first polymeric structures or the second polymeric structures forming a polymeric mask;
forming second trenches in the one or more masks utilizing the polymeric mask;
forming a sacrificial material in the second trenches;
removing remaining portions of the one or more masks to form third trenches through the sacrificial material and expose upper surfaces of the first conductive structures;
removing portions of the first conductive structures exposed by the third trenches to form first conductive members having openings therebetween;
forming second conductive structures adjacent to at least one sidewall of at least one of the semiconductor pillars; and
forming third conductive structures adjacent to second ends of the semiconductor pillars.

2. The method as recited in claim 1, wherein forming first insulative structures in the first trenches each having a second insulative structure therein comprises forming the second insulative structures comprising phosphorus doped polysilicon.

3. The method as recited in claim 1, wherein forming the block copolymer adjacent to the neutral layer mask comprises depositing a polystyrene-block-poly(methyl methacrylate) block copolymer adjacent to the neutral layer mask.

4. The method as recited in claim 1, wherein annealing the block copolymer to form the self-assembled array of first polymeric structures and second polymeric structures comprises annealing the block copolymer at a temperature of from about 240 degrees Celsius to about 280 degrees Celsius.

5. The method as in claim 1, wherein forming first insulative structures in the first trenches comprises forming the first insulative structures each including a lower section having a first width and an upper section having a second width, the first width being greater than the second width.

6. The method as in claim 5, wherein forming first insulative structures in the first trenches comprises forming the first insulative structures each including the lower section having the first width of from about 10 nm to about 40 nm and the upper section having the second width of from about 5 nm to about 20 nm.

7. The method as recited in claim 1, wherein selectively removing the first polymeric structures or the second polymeric structures, comprises selectively removing the first polymeric structures or the second polymeric structures wherein the remaining first polymeric structures or the remaining second polymeric structures have a diameter of from about 2 nm to about 100 nm.

8. The method as recited in claim 1, wherein selectively removing the first polymeric structures or the second polymeric structures, the remaining one of the first polymeric structures or the second polymeric structures forming a polymeric mask comprises selectively removing the first polymeric structures or the second polymeric structures, the remaining one of the first polymeric structures or the second polymeric structures forming a polymeric mask having fourth trenches between the remaining one of the first polymeric structures or the second polymeric structures, the fourth trenches having third widths of from about 5 nm to about 45 nm.

9. The method as recited in claim 1, wherein removing portions of the first conductive structures exposed by the third trenches to form first conductive members having openings therebetween comprises removing portions of the first conductive structures exposed by the third trenches to form first conductive members having openings separating the first conductive members from one another, the openings having fourth widths of from about 2 nm to about 100 nm.

10. A method of forming a microelectronic device, comprising:
forming a semiconductor structure having a base;
forming first trenches extending into the semiconductor structure in a first direction and disposed in parallel with one another in a second direction, semiconductor pillars being formed and interposed between adjacent ones of the first trenches in the second direction;
forming insulative structures in the first trenches, the insulative structures comprising:
a lower section exhibiting a first width at least partially defined by a horizontal distance between sidewalls of neighboring semiconductor pillars in the second direction;
an upper section exhibiting a second width at least partially defined by a horizontal distance between sidewalls thereof in the second direction, the first width being greater than the second width; and
shoulder regions formed between the sidewalls of the lower section of the insulative structure and the sidewalls of the upper section of the insulative structure;
forming first conductive structures adjacent to first ends of the semiconductor pillars and extending adjacent to the shoulder regions of neighboring insulative structures;
removing portions of the first conductive structures to form first conductive members having openings therebetween;
forming second conductive structures adjacent to one of the sidewalls of at least one of the semiconductor pillars; and
forming third conductive structures adjacent to second ends of the semiconductor pillars.

11. The method as recited in claim 10, wherein forming the semiconductor structure comprises forming the semiconductor structure comprising silicon.

12. The method as recited in claim 10, wherein forming insulative structures in the first trenches comprises forming insulative structures in the first trenches having lower sections with first widths in a range of from about 10 nanometers to about 40 nanometers.

13. The method as recited in claim 12, wherein forming insulative structures in the first trenches comprises forming insulative structures in the first trenches having upper sections with second widths in a range of from about 5 nanometers to about 20 nanometers.

14. The method as recited in claim 13, wherein forming first conductive structures adjacent to first ends of the semiconductor pillars and extending adjacent to the shoulder regions of neighboring insulative structures comprises forming first conductive structures adjacent to first ends of the semiconductor pillars and extending adjacent to sidewalls of the upper sections of neighboring insulative structures.

15. The method as recited in claim 10, wherein forming first conductive structures adjacent to first ends of the semiconductor pillars and extending adjacent to the shoulder regions of neighboring insulative structures comprises forming first conductive structures adjacent to first ends of the semiconductor pillars and extending adjacent to sidewalls of the upper sections of neighboring insulative structures.

16. The method as recited in claim 10, wherein forming second conductive structures adjacent to one of the sidewalls of at least one of the semiconductor pillars comprises forming second trenches at least partially through the semiconductor pillars and forming the second conductive structures in the second trenches.

17. The method as recited in claim 16, wherein forming the second conductive structures in the second trenches comprises forming a dielectric liner in each of the second trenches and forming the second conductive structures on the dielectric liners in the second trenches.

18. A microelectronic device, comprising:
insulative structures disposed in a first direction and interposed between and alternating with semiconductor pillars in a second direction, each insulative structure comprising:
a lower section exhibiting a first width at least partially defined by a distance between sidewalls of neighboring semiconductor pillars in the second direction;
an upper section exhibiting a second width at least partially defined by a distance between sidewalls thereof in the second direction, wherein the first width is greater than the second width; and
shoulder regions between the sidewalls of the lower section of the insulative structure and the sidewalls of the upper section of the insulative structure; and
one or more vertical access devices, the vertical access devices comprising:
one of the semiconductor pillars, the one of the semiconductor pillars having oppositely disposed source/drain regions and a channel region vertically between the source/drain regions;
a gate electrode adjacent to the one of the semiconductor pillars and in electrical communication therewith;
a first conductive member adjacent to one end of the one of the semiconductor pillars and extending adjacent to the shoulder regions of neighboring insulative structures, the first conductive member in electrical communication with one of the source/drain regions; and
a conductive structure in electrical communication with the other of the source/drain regions.

19. The microelectronic device of claim 18, wherein the first conductive members comprise an enlarged active area at least partially defined by portions of the first conductive members which extend adjacent to the shoulder regions of the neighboring insulative structures and to the sidewalls of the upper sections thereof.

20. The microelectronic device of claim 18, wherein the microelectronic device comprises a dynamic random-access memory (DRAM) device.
